(19) United States
(12) Patent Application Publication
(10) Pub. No.: US 2012/0202346 A1
(43) Pub. Date: Aug. 9, 2012

(54) METHOD FOR MANUFACTURING A SEMICONDUCTOR DEVICE

(75) Inventors: Toshinobu SAKANAKA, Oita-ken (JP); Keiji FUJITA, Oita-ken (JP)

(73) Assignee: KABUSHIKI KAISHA TOSHIBA, Tokyo (JP)

(21) Appl. No.: 13/365,479

(22) Filed: Feb. 3, 2012

(30) Foreign Application Priority Data
Feb. 7, 2011 (JP) 2011-023998

(51) Int. Cl. H01L 21/768

(52) U.S. Cl. 438/666; 257/E21.577

(57) ABSTRACT

Certain embodiments provide a method for manufacturing a semiconductor device including forming first and second insulating films on first and second regions formed on a semiconductor substrate, respectively, selectively irradiating UV light to a second contact region where the second contact is to be formed in the second insulating film, forming first and second opening on the first and second insulating films by concurrently etching a first contact region in the first insulating film where the first contact is to be formed and the second contact region after having irradiated the UV light, respectively, forming first and second contacts in the first and second openings. The second insulating film differs from the first insulating film in the membrane stress, and is an insulating film with an etching rate that approaches an etching rate of the first insulating film by the UV light being irradiated.

### CROSS REFERENCE TO RELATED APPLICATIONS

This application is based upon and claims the benefit of priority from the prior Japanese Patent Application No. 2011-023998 filed in Japan on Feb. 7, 2011; the entire contents of which are incorporated herein by reference.

### FIELD

Embodiments described herein relate generally to method for manufacturing a semiconductor device.

### BACKGROUND

In the recent years, in accordance with miniaturization and sophistication of an electric apparatus and the like, for example, in CMOS transistors configuring a SRAM (Static Random Access Memory) cell and the like, an improvement in carrier mobility is demanded in order to improve driving power.

The carrier mobility depends on stresses caused by a phase orientation, an axial direction, a lattice strain and the like of a substrate onto which an element is to be formed, and a direction along which the carrier mobility is improved or deteriorated differs depending on carriers.

For example, in forming an n-type transistor and a p-type transistor with a <110> axial direction of a (100) face of an Si substrate as a channel longitudinal direction, in the n-type transistor the carrier mobility can be improved by providing a tensile stress in an (X direction) and a direction vertical to a substrate surface (Z direction), whereas in the p-type transistor, the carrier mobility can be improved by providing a compressive stress in the (X direction) and the direction vertical to the substrate surface (Z direction).

Such tensile stress and compressive stress are provided by causing a film character of a barrier film (insulating film) such as SiN formed on a gate electrode to be different for each element.

### BRIEF DESCRIPTION OF THE DRAWINGS

FIG. 1 shows a flow chart of a method for manufacturing a semiconductor device of a first embodiment.

FIG. 2 is a diagram showing the manufacturing process of the semiconductor device of the first embodiment.

FIG. 3 is also a diagram showing the manufacturing process of the semiconductor device of the first embodiment.

FIG. 4 is a graph showing a relationship of irradiation time of UV light and an etching rate of an SiN film upon irradiating the UV light to a Tensile SiN film.

FIG. 5 is a graph showing a relationship of irradiation time of UV light and an etching rate of an SiN film upon irradiating the UV light to a Compressive SiN film.

FIG. 6 is a diagram showing processing shapes of substrate contacts of the first embodiment.

FIG. 7 is a diagram showing conventional processing shapes of substrate contacts.

FIG. 8 shows a flow chart of a method for manufacturing a semiconductor device of a second embodiment.

FIG. 9 is a diagram showing a manufacturing process of the semiconductor device of the second embodiment.

FIG. 10 is a top view showing the semiconductor device formed by the manufacturing method for an embodiment.

FIG. 11 is a sectional view of the device taken along A-A′ of FIG. 10.

### DETAILED DESCRIPTION

Certain embodiments provide a method for manufacturing a semiconductor device having an element region formed on a semiconductor substrate and including a first region and a second region, a first contact connected to the first region, and a second contact connected to the second region. The method includes forming the element region on the semiconductor substrate; forming a first insulating film on the first region; forming a second insulating film on the second region; irradiating UV light; forming a first opening on the first insulating film and a second opening on the second insulating film; and forming the first contact in the first contact and the second contact in the second opening. The second insulating film differs from the first insulating film in the membrane stress, and is an insulating film with an etching rate that approaches an etching rate of the first insulating film by the UV light being irradiated. Irradiating the UV light is selectively irradiating the UV light to the second contact region where the second contact is to be formed in the second insulating film. Forming the first opening and the second opening is forming the first opening on the first insulating film and the second opening in the second insulating film by concurrently etching the first contact region in the first insulating film where the first contact is to be formed and the second contact region after having irradiated the UV light.

Hereinbelow, embodiments of a method for manufacturing a semiconductor device will be explained. Note that, hereinbelow, a semiconductor device including an n-type transistor and a p-type transistor, and contacts, arranged on impurity regions of these transistors, that are electrically connected to these impurity regions will be used as an example of the semiconductor device, and a method for manufacturing such a semiconductor device will be explained.

### First Embodiment

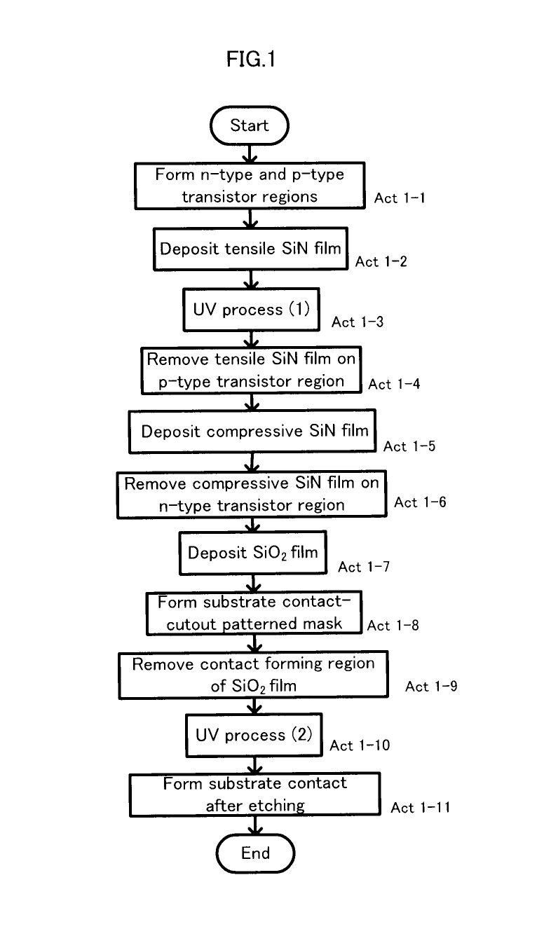

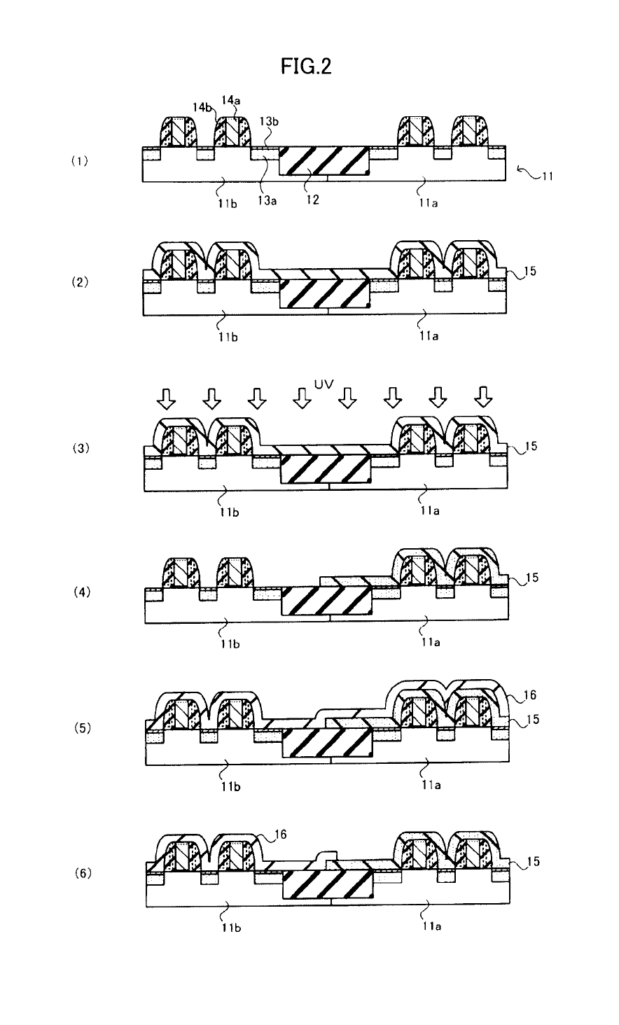

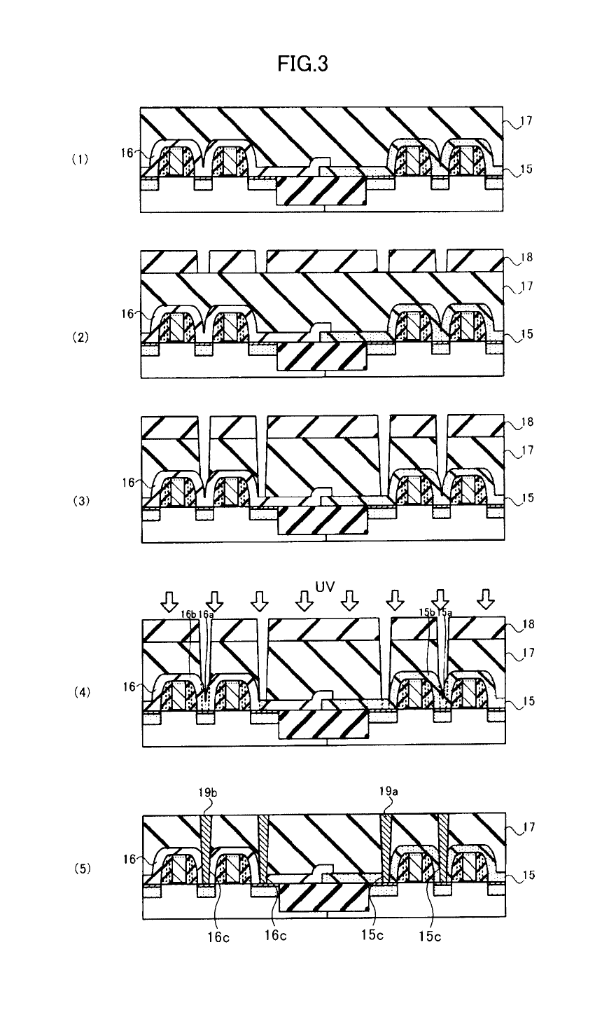

FIG. 1 shows a flow chart of a method for manufacturing a semiconductor device of the present embodiment. Further, cross sectional views of the device are shown in FIG. 2 and FIG. 3 for explaining the method for manufacturing the semiconductor device of the present embodiment.

Firstly, as shown in FIG. 2 (1), an n-type transistor region 11a and a p-type transistor region lib are formed on a semiconductor substrate 11 (Act 1-1). The n-type transistor region 11a and the p-type transistor region 11b are formed as follows.

Firstly, an STI (Shallow Trench Isolation) 12 is formed on the semiconductor substrate 11, and separates a region where the n-type transistor region 11a is to be formed and a region where the p-type transistor region 11b is to be formed. Next, in each of the separated regions, an impurity diffused region 13a, a silicide film 13b, a gate electrode 14a, and a gate side wall 14b are formed. Accordingly, the n-type transistor region 11a and the p-type transistor region 11b are formed.

Next, as shown in FIG. 2 (2), an SiN film 15 (Tensile SiN film) for providing a tensile stress to the n-type transistor region 11a is deposited on the n-type transistor region 11a and the p-type transistor region 11b as a barrier film (insulating film) (Act 1-2). The SiN film 15 is an SiN film having a film density (a number of atoms (or mass) per a unit volume) that is low enough for its etching rate to decrease as the UV is irradiated thereon, and is formed at a film thickness, for example, of about 20 to 500 nm by using a parallel plate type of a PE-CVD (Plasma-Enhanced Chemical Vapor Deposition) device, for example. A condition for depositing the SiN film 15 is, for example: pressure: 1 to 10 Torr, substrate temperature: 300 to 500° C., gas flow rate: SiH₄/NH₃/N₂=10 to 500/500 to 5000/50 to 5000 sccm, RF: 13.56 MHz/50 to 300 W, and electrode distance: 5 to 10 mm.

Note that, since the film density of the SiN film 15 should be low, the SiN film 15 is deposited under the aforementioned low temperature/low power condition.

Next, as shown in FIG. 2 (3), the UV light is irradiated on the SiN film 15 to increase the tensile stress (UV process (1)) (Act 1-3). In the UV process (1), the UV light is irradiated, for example, at intensity of 300 to 2000 W/cm² for a total of 200 to 1000 seconds. The deposition of the SiN film 15 shown in FIG. 2 (2) and the UV process (1) shown in FIG. (3) may alternately be performed for a plurality of times.

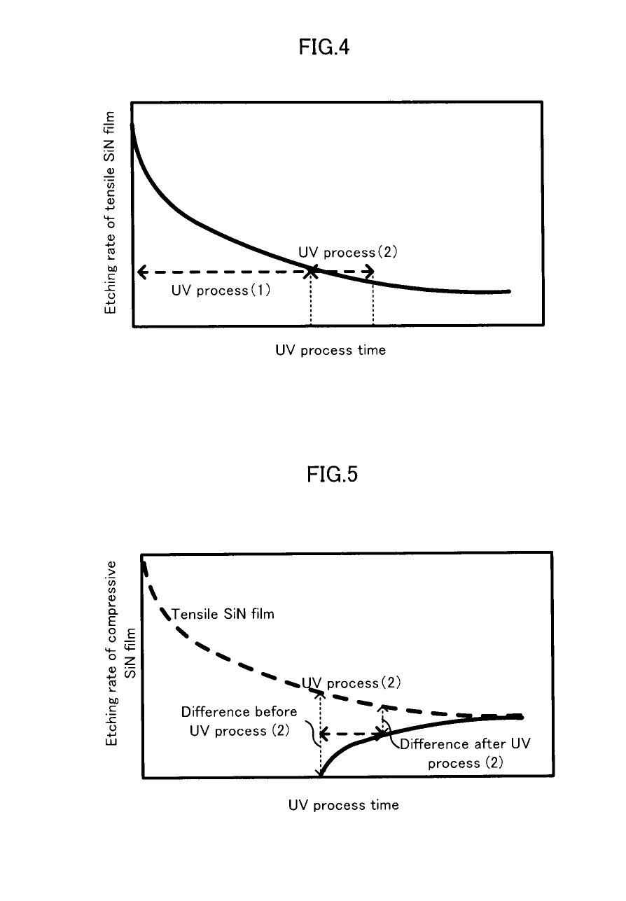

FIG. 4 is a graph showing a relationship of the irradiation time of the UV light and the etching rate of the SiN film 15 upon irradiating the UV light to the SiN film 15. As shown in FIG. 4, when the UV light is irradiated, the etching rate of the SiN film 15 becomes smaller. Further, the change in the etching rate by the UV light irradiation becomes smaller as the irradiation time of the UV light becomes longer.

As shown in FIG. 4, by the UV process (1), the etching rate of the SiN film 15 in a step shown in FIG. 3 (5) described later (during an etching process upon forming substrate contacts) is decreased. A reason why the etching rate changes accordingly is assumed to be as follows.

The deposited SiN film 15 is a film having a large number of Si—H bonding and N—H bonding, and having a relatively sparse film density. When the UV is irradiated onto such a SiN film 15, the Si—H bonding and the N—H bonding are once cut off, where H breaks away, and Si and N bonds again (whereby forming Si—N bonding). Due to this, the film density of the SiN film 15 becomes more dense than prior to the UV irradiation, so the etching rate decreases by the UV irradiation.

Next, as shown in FIG. 2 (4), the SiN film 15 on the p-type transistor region 11b is removed (Act 1-4). The SiN film 15 is removed, for example, by a method such as a photo lithography etching process (hereafter referred to as PEP) and the like.

Next, as shown in FIG. 2 (5), an SiN film 16 (Compressive SiN film) for providing a compressive stress to the p-type transistor region 11b is deposited on the n-type transistor region 11a and the p-type transistor region 11b where the SiN film 15 still remains as a barrier film (insulating film) (Act 1-5). The SiN film 16 is an SiN film having a film density that is high enough for its etching rate to increase as the UV is irradiated thereon, and is formed at a film thickness, for example, of about 20 to 500 nm by using the parallel plate type of the PE-CVD (Plasma-Enhanced Chemical Vapor Deposition) device, for example, similar to the SiN film 15. However, a condition for depositing the SiN film 16 is different from the condition for depositing the SiN film 15, and is for example: pressure: 1 to 10 Torr, substrate temperature: 300 to 500° C., gas flow rate: SiH₄/NH₃/N₂/H₂/Ar=10 to 500/500 to 5000/100 to 5000/0 to 10000/0 to 5000 sccm, RF (SiH₄/NH₃/N₂): 13.56 MHz/50 to 1000 W, RF (H₂/Ar): 300 to 500 kHz/0 to 100 W, and electrode distance: 5 to 10 mm.

Note that, since a film density of the SiN film 16 should be high, the SiN film 16 further uses H₂ gas and Ar gas that are not used in forming the SiN film 15 as above, and is formed by further applying an RF of low frequency. When the SiN film is formed as above, the SiN film 16 with high film density is formed by striking H and Ar onto the film and forcing a distance between atoms in the Si—N bonding to narrow.

The UV process (1) is performed on the SiN film 15 upon forming the SiN film 15, but no UV process is performed on the SiN film 16 upon forming the SiN film 16. This is because if the UV process is performed on the SiN film 16, a film stress thereof decreases.

Next, as shown in FIG. 2 (6), the SiN film 16 on the n-type transistor region 11a is removed (Act 1-6). The SiN film 16 is removed, for example, by a method such as the PEP and the like.

By going through the respective processes as above, the SiN film 15 (Tensile SiN film) for providing the tensile stress to the region 11a is formed on the n-type transistor region 11a, and the SiN film 16 (Compressive SiN film) for providing the compressive stress to the region 11b is formed on the p-type transistor region 11b.

After the SiN film 15 and the SiN film 16 are formed at predetermined positions, as shown in FIG. (1), an SiO₂ film 17 is formed on the SiN films 15, 16 as a barrier film (insulating film) (Act 1-7).

Next, as shown in FIG. 3 (2), a mask 18 (of a substrate contact-cutout) covering a region except for regions where substrate contacts are to be formed is formed on the SiO₂ film 17 (Act 1-8). This mask 18 is formed by performing a patterning process after having applied a resist of an entire surface of the SiO₂ film 17. As the resist applied on the SiO2 film 17, a resist (for example, a resist with an absorbtivity of the UV light of 10% or more) having a property to attenuate (absorb) the UV light (wavelength of 200 nm or less) is used.

Next, as shown in FIG. 3 (3), of the SiO₂ film 17, the regions where the substrate contacts are to be formed (hereafter referred to as contact forming regions) are selectively removed. (Act 1-9). The SiO₂ film 17 is selectively removed by performing an etching process such as an RIE (Reactive Ion Etching) on the SiO₂ film 17 using the mask 18.

Next, as shown in FIG. 3 (4), the UV light is irradiated on the mask 18 (UV process (2)) (Act 1-10). In the UV process (2), the UV light is irradiated, for example, at intensity of 300 to 2000 W/cm² for a total of 50 to 500 seconds.

In this UV process (2), the UV light is irradiated on contact forming regions 15a, 16a of the SiN films 15, 16 where the mask 18 is not formed. However, since the UV light is absorbed by the resist (mask 18), the UV light does not reach regions 15b, 16b of the SiN films 15, 16 covered by the mask 18.

The SiN film 15 already has the UV process performed by the UV process (1). Accordingly, as show in FIG. 4, even if the UV light is irradiated again on the contact forming region 15a (SiN film 15) by the UV process (2), the change in the etching rate of the contact forming region 15a is small.

FIG. 5 is a graph showing a relationship of the irradiation time of UV light and the etching rate of the SiN film 16 upon irradiating the UV light to the SiN film 16. As shown in FIG. 5, the etching rate of the SiN film 16 to which the UV light is not irradiated is lower than the etching rate of the SiN film 15, however, when the UV light is irradiated, the etching rate of the SiN film 16 increases. The change in the etching rate of the SiN film 16 by the UV light irradiation becomes smaller as the irradiation time of the UV light becomes longer.

As shown in FIG. 5, by the UV process (2), the etching rate of the SiN film 16 in a step shown in FIG. 3 (5) described later (during the etching process upon forming the substrate contacts) (hereafter referred to simply as the etching rate) is increased, and a difference with the etching rate of the contact forming region 15a becomes smaller. A reason why the etching rate changes accordingly is assumed to be as follows.

The deposited SiN film 16 is a film having a smaller number of Si—H bonding and N—H bonding than the SiN film 15, and having a relatively dense film density. When the UV is irradiated onto such SiN film 16, similar to the SiN film 15, the S—H bonding and the N—H bonding are once cut off, where H breaks away, and Si and N bonds again (whereby forming Si—N bonding). However, since the number of the Si—H bondings and the N—H bondings is small, even if the UV is irradiated, the number of the Si—N bondings does not increase so much.

However, in the Si—N bonding included in the SiN film 16, the distance between atoms of Si and N is made narrow. When the UV is irradiated onto this SiN film 16, the Si—N bonding is cut off, where H breaks away, and the distance of atoms of Si and N returns to their normal distance when Si and N bonds again. Due to this, the film density of the SiN film 16 is made more sparse than prior to the UV irradiation. Accordingly, the etching rate increases by the UV irradiation.

After having performed the UV process on the contact forming regions 15a, 16a as above, as shown in FIG. 3 (5), the contact forming regions 15a, 16a are removed by etching such as the RIE method, and respectively forms openings 15c, 16c on the SiN film 15 and the SiN film 16. Thereafter, metal layers such as Ti/W are embedded in the regions where the SiO₂ film 17 is removed and the openings 15c, 16c. Thereby the substrate contacts 19a, 19b are formed (Act 1-11).

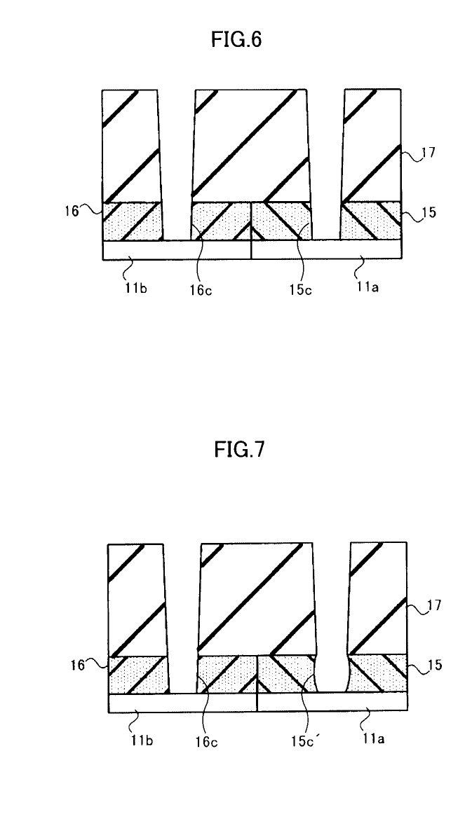

FIG. 6 is a diagram for explaining states of the contact forming regions 15a, 16a after having etched. By performing the UV process on the SiN films 15, 16 prior to forming the substrate contacts 19a, 19b, as shown in FIG. 5, the difference in the etching rates upon forming the substrate contacts 19a, 19b on the n-type transistor region 11a and the p-type transistor region 11b can be made small. Accordingly, even if the SiN film 15 and the SiN film 16 are concurrently etched, as shown in FIG. 6, the etching can be performed such that an etching amount of the SiN film 15 and an etching amount of the SiN film 16 both come to be at etching amounts as planned. Accordingly, a shape of the opening 15c formed on the SiN film 15 and a shape of the opening 16c formed on the SiN film 16 can both be in shapes as planned, so variations in the shape of the opening 15c and the shape of the opening 16c can be suppressed.

FIG. 7 is a diagram for explaining states of the contact forming regions 15a, 16a after having etched in a case where the UV process (2) had not been performed on the SiN film 16. Especially, in the case of not performing the UV process (2) on the SiN film 16, if the etching condition is adjusted so that the contact forming region 16a is etched by the etching amount as planned, the SiN film 15 is over-etched (etched excessively), and as shown in FIG. 7, an opening 15c′ formed by the SiN film 15 being removed is widened to a side (a substrate surface direction), or a SALICIDE of a lower part thereof is damaged.

Contrary to this, if the etching condition is adjusted so that the contact forming region 15a is etched at the etching amount as planned, the SiN film 16 is under-etched, and a part of the SiN film 16 that should be removed remains.

Accordingly, in the case of not suitably irradiating the UV light to the SiN film 15 and the SiN film 16, a shape of the opening 15c and a shape of opening 16c that are formed vary due to the difference in their etching rates.

According to the present embodiment, the over-etching of the SiN film 15 and the under-etching of the SiN film 16 are suppressed, and the variation in the shapes of the substrate contacts 19a, 19b and the etching variation can be suppressed. Further, since the UV process is performed only on the contact forming regions 15a, 16a, no influence is imposed on the film property (membrane stress and the like) of the remaining SiN film 15b and SiN film 16b by the UV irradiation.

As aforementioned, according to the present embodiment, in forming the substrate contacts in the SiN films having film properties different from one another such as respectively having the tensile stress and the compressive stress, even if the concurrent etching is performed, the variation in the shape of the openings formed in the SiN films by the etching can be suppressed. Thus, a control performance of eh shapes in forming the substrate contacts can be improved. Further, in addition to suppressing the variation in the shapes of the substrate contacts and stabilizing a property of a semiconductor device, a decrease in yield caused by a margin being curtailed according to the miniaturization of the semiconductor device can be suppressed.

### Second Embodiment

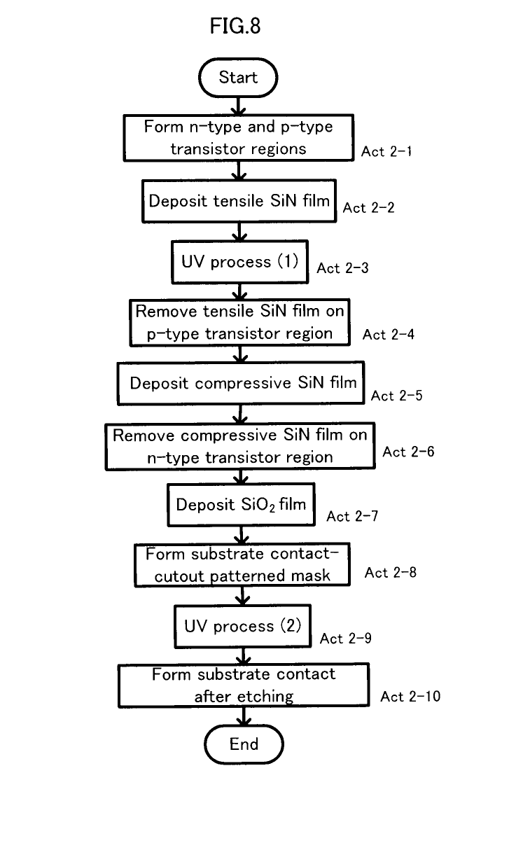

FIG. 8 shows a flow chart of a method for manufacturing a semiconductor device of the present embodiment. The embodiment shown in FIG. 8 differs from the first embodiment in that the UV process is performed prior to etching the SiO₂ film by the RIE; each of the processes of Act 2-1 to Act 2-8 shown in FIG. 8 is identical to the corresponding one of Act 1-1 to Act 1-8 shown in FIG. 3. That is, in the present embodiment, from a step of forming an n-type transistor 21a and a p-type transistor 21b that is separated by an STI (Shallow Trench Isolation) 22 is formed on a semiconductor substrate 21 (Act 2-1) to a step of, after having formed an SiN film 25 (Tensile SiN film) and an SiN film 26 (Compressive SiN film), forming a mask 28 (having a pattern with substrate contacts cut out) covering a region except for regions where the substrate contacts are formed on an SiO2 film 27 on the SiN films 25, 26 (Act 2-8) are identical to the first embodiment. Hereafter, in the explanation of the present embodiment, respective steps after the step of forming the mask 28 will be explained.

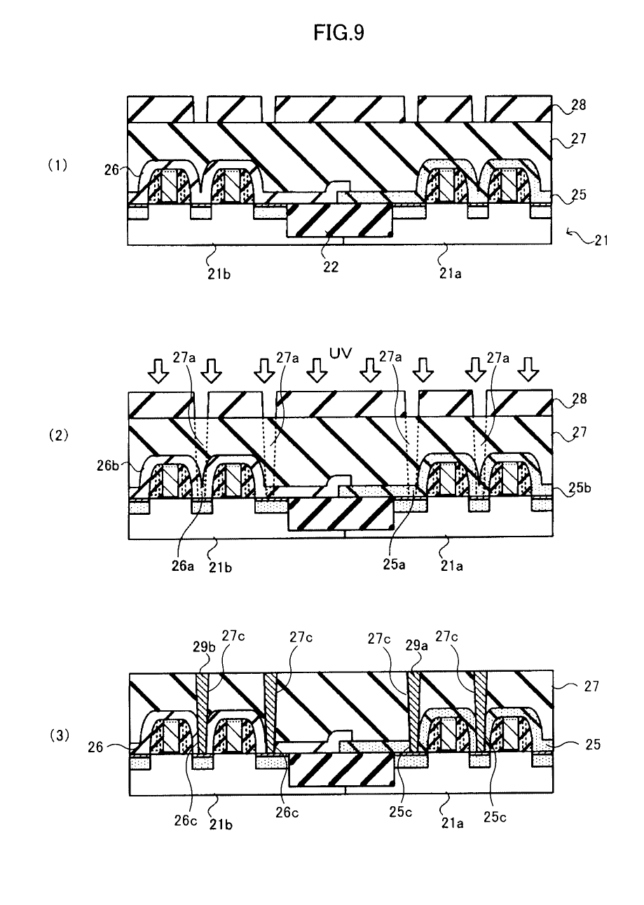

FIG. 9 shows a cross sectional view of a device for explaining the steps after the step of forming the mask 28 in a method for manufacturing the semiconductor device of the present embodiment.

As shown in FIG. 9 (1), after having formed the mask 28 on the SiO₂ film 27, as shown in FIG. 9 (2), UV light is irradiated on the mask 28 (UV process (2)) (Act 2-9). In the UV process (2), the UV light is irradiated, for example, at intensity of 300 to 2000 W/cm2 for a total of 50 to 500 seconds.

In this step, the UV light is irradiated with contact forming regions 27a in the SiO₂ film 27 not being removed. However, since the SiO₂ film is transparent to the UV light, so the UV light irradiated on the mask 28 does not attenuate at the SiO₂ film 27, and reaches the SiN films 25, 26. Accordingly, in this step, the UV process is performed on the contact forming regions 25a, 26a of the SiN films 25, 26.

Accordingly, after having performed the UV process on the contact forming regions 25a, 26a, as shown in FIG. 8 (3), the contact forming regions 27a of the SiO₂ film 27 and the contact forming regions 25a, 26a of the SiN films 25, 26 are successively removed by the etching, for example, by the RIE and the like, and the openings 27c, 25c, 26c are formed on the SiO₂ film 27 and the SiN films 25, 26, respectively. Then, the metal layers such as Ti/W are embedded in the openings 27c, 25c, 26c. Due to this, substrate contacts 29a, 29b are formed (Act 2-10).

Accordingly, by performing the UV process (2) prior to removing the SiO₂ film 27, the SiN films 25, 26 can be etched succeedingly after having etched the SiO₂ film 27. Further, similar to the first embodiment, by performing the UV process prior to forming the substrate contacts 29a, 29b on the SiN films 25, 26, the difference in the etching rates upon forming the substrate contacts 29a, 29b on the n-type transistor 21a and the p-type transistor 21b can be made small. Accordingly, even if the SiN film 25 and the SiN film 26 are concurrently etched, the etching can be performed such that the etching amount of the SiN film 25 and the etching amount of the SiN film 26 both come to be at etching amounts as planned. Accordingly, a shape of the opening 25c formed on the SiN film 25 and a shape of the opening 26c formed on the SiN film 26 can both be in shapes as planned, so variations in the shape of the opening 25c and the shape of the opening 26c can be suppressed.

Especially, in the case of not performing the UV process (2) on the SiN film 26, if the etching condition is adjusted so that the contact forming region 26a is etched by the etching amount as planned, the SiN film 25 is over-etched (etched excessively), and an opening formed by the SiN film 25 being removed is widened to a side (a substrate surface direction), or a SALICIDE of a lower part thereof is damaged.

Contrary to this, if the etching condition is adjusted so that the contact forming region 25a is etched at the etching amount as planned, the SiN film 26 is under-etched, and a part of the SiN film 26 that should be removed remains.

Accordingly, in the case of not suitably irradiating the UV light to the SiN film 25 and the SiN film 26, the shape of the opening 25c and the shape of opening 26c that are formed vary due to the difference in their etching rates.

According to the present embodiment, the over-etching of the SiN film 25 and the under-etching of the SiN film 26 are suppressed, and the variation in the shapes of the substrate contacts 29a, 29b and the etching variation can be suppressed. Further, since the UV process is performed only on the contact forming regions 25a, 26a, no influence is imposed on the film property (membrane stress and the like) of the remaining SiN film 25b and SiN film 26b by the UV irradiation.

As aforementioned, according to the present embodiment also, similar to the first embodiment, in forming the substrate contacts in the SiN films having film properties different from one another such as respectively having the tensile stress and the compressive stress, even if the concurrent etching is performed, the variation in the shape of the openings formed in the SiN films by the etching can be suppressed. Thus, a control performance of eh shapes in forming the substrate contacts can be improved. Further, in addition to suppressing the variation in the shapes of the substrate contacts and stabilizing a property of a semiconductor device, a decrease in yield caused by a margin being curtailed according to the miniaturization of the semiconductor device can be suppressed.

Further, according to the present embodiment, by performing the UV process (2) prior to removing the SiO₂ film 27, the SiN films 25, 26 can be etched succeedingly after having etched the SiO₂ film 27. Accordingly, compared to the first embodiment, the semiconductor device can be manufactured more easily.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

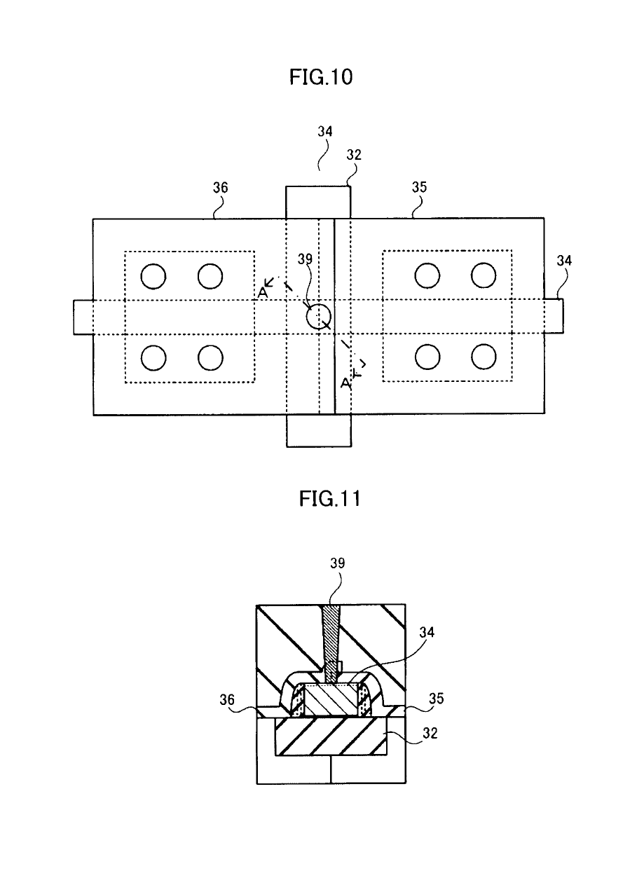

For example, as the top view is shown in FIG. 10 and the partial cross sectional view along its A-A′ is shown in FIG. 11, in the case of forming the contact 39 on the gate electrode 34 on the STI 32, in forming this contact 39 on a region where the SiN film 35 providing the tensile stress and the SiN film 36 providing the compressive stress are overlapped, by adapting one of the first embodiment and the second embodiment, the etching rate of the SiN film 36 can be increased, and the difference in the etching rates of the SiN film 35 and the SiN film 36 can be suppressed. Accordingly, stable contact shapes can be obtained, and a variation in contact resistances can be suppressed.

Further, in the UV process (2) in each of the aforementioned embodiments, although the UV process is performed on both of the contact forming regions of both SiN films having the different film property, the UV process does not necessarily have to be performed on both of them (entire surface). That is, the UV light may be irradiated only on one of the SiN films such that the difference in the etching rates of the two SiN films having the different film property becomes small. For example, in the UV process (2), by performing the UV process only on the contact forming region of the SiN film to which the UV process is not predeterminedly performed (the SiN film providing the compressive stress), the difference in the etching rates of the two SiN films having the different film properties can be made small. Note that, in this case, prior to performing the UV process (2), the SiN film onto which the UV process is predeterminedly performed needs to be masked.

What is claimed is:

1. A method for manufacturing a semiconductor device, the semiconductor device having an element region including a first region and a second region formed on a semiconductor substrate, a first contact connected to the first region, and a second contact connected to the second region, the method comprising:
forming the element region on the semiconductor substrate;
forming a first insulating film of the first region;
forming a second insulating film on the second region, the second insulating film having a different membrane stress from that of the first insulating film and an etching rate that approaches an etching rate of the first insulating film by the UV light being irradiated;
selectively irradiating the UV light to a second contact region in the second insulating film where the second contact is to be formed;
forming a first opening on the first insulating film and a second opening on the second insulating film by concurrently etching a first contact region in the first insulating film where the first contact is to be formed and the second contact region after having irradiated the UV light; and
forming the first contact in the first opening and forming the second contact in the second opening.

2. The method for manufacturing a semiconductor device according to claim 1, further forming a mask covering the second insulating film except for the second contact region by a resist film that attenuates the UV light prior to irradiating the UV light,
wherein irradiating the UV light is selectively irradiating the UV light to the second contact region via the mask.

3. The method for manufacturing a semiconductor device according to claim 2,
wherein forming the mask is forming a third insulating film that transmits the UV light on the first insulating film and the second insulating film, and thereafter forming the mask on this third insulating film.

4. The method for manufacturing a semiconductor device according to claim 3, further patterning the third insulating film by using the mask prior to irradiating the UV light,
wherein irradiating the UV light is irradiating the UV light via the mask.

5. The method for manufacturing a semiconductor device according to claim 3, wherein irradiating the UV light is irradiating the UV light via the mask and the third insulating film.

6. The method for manufacturing a semiconductor device according to claim 2,
wherein the first region is an n-type transistor region and the first insulating film is an SiN film providing a tensile stress on a channel of this n-type transistor region, and
the second region is a p-type transistor region and the second insulating film is an SiN film providing a compressive stress on a channel of this p-type transistor region.

7. The method for manufacturing a semiconductor device according to claim 1,
wherein the first insulating film is an insulating film with the etching rate that approaches the etching rate of the second insulating film by the UV light being irradiated,
wherein irradiating the UV light is selectively irradiating the UV light to the first contact region where the first contact is to be formed in the first insulating film and the second contact region.

8. The method for manufacturing a semiconductor device according to claim 7, further comprising forming a mask covering the first insulating film and the second insulating film except for the first contact region and the second contact region by a resist film that attenuates the UV light prior to irradiating the UV light,
wherein irradiating the UV light is selectively irradiating the UV light to the first contact region and the second contact region via the mask.

9. The method for manufacturing a semiconductor device according to claim 8,
wherein forming the mask is forming a third insulating film that transmits the UV light on the first insulating film and the second insulating film, and thereafter forming the mask on this third insulating film.

10. The method for manufacturing a semiconductor device according to claim 9, further comprising patterning the third insulating film by using the mask prior to irradiating the UV light,
wherein irradiating the UV light is irradiating the UV light via the mask.

11. The method for manufacturing a semiconductor device according to claim 9, wherein irradiating the UV light is irradiating the UV light via the mask and the third insulating film.

12. The method for manufacturing a semiconductor device according to claim 7,
wherein the first region is an n-type transistor region and the first insulating film is an SiN film providing a tensile stress on a channel of this n-type transistor region, and
the second region is a p-type transistor region and the second insulating film is an SiN film providing a compressive stress on a channel of this p-type transistor region.

13. The method for manufacturing a semiconductor device according to claim 1,
wherein the first insulating film is an insulating film with the etching rate that approaches the etching rate of the second insulating film by the UV light being irradiated,
wherein irradiating the UV light is selectively irradiating the UV light to the first contact region where the first contact is to be formed in the first insulating film and the second contact region.

14. The method for manufacturing a semiconductor device according to claim 13, further forming a mask covering the first insulating film and the second insulating film except for the first contact region and the second contact region by a resist film that attenuates the UV light prior to irradiating the UV light,
wherein irradiating the UV light is selectively irradiating the UV light to the first contact region and the second contact region via the mask.

15. The method for manufacturing a semiconductor device according to claim 14, wherein forming the mask is forming a third insulating film that transmits the UV light on the first insulating film and the second insulating film, and thereafter forming the mask on this third insulating film.

16. The method for manufacturing a semiconductor device according to claim 15, further patterning the third insulating film by using the mask prior to irradiating the UV light,
wherein irradiating the UV light is irradiating the UV light via the mask.

17. The method for manufacturing a semiconductor device according to claim 15, wherein irradiating the UV light is irradiating the UV light via the mask and the third insulating film.

18. The method for manufacturing a semiconductor device according to claim 13,
wherein the first region is an n-type transistor region and the first insulating film is an SiN film providing a tensile stress on a channel of this n-type transistor region, and
the second region is a p-type transistor region and the second insulating film is an SiN film providing a compressive stress on a channel of this p-type transistor region.
